(19) United States
(12) Patent Application Publication
(10) Pub. No.: US 2004/0169224 A1
(43) Pub. Date: Sep. 2, 2004

(54) Semiconductor device and manufacturing method therefor

(76) Inventor: Mika Ebihara, Chiba-shi (JP)

Correspondence Address: ADAMS & WILKS, 31st Floor, 50 Broadway, New York, NY, 10004, US

(21) Appl. No.: 10/750,006

(22) Filed: Dec. 30, 2003

(30) Foreign Application Priority Data
Jan. 15, 2003 (JP) 2003-006629

(51) Int. Cl. H01L 29/76

(52) U.S. Cl. 257/344

(57) ABSTRACT

The present invention has an object to provide a MOS type transistor with a simple process, in which a high concentration junction can be stably formed so shallowly as to prevent a high concentration region constituting a drain/source region from extending beyond a contact hole due to a production variation, which cannot be attained by a conventional MOS type transistor of an LDD structure. The present invention having the following feature. That is, in forming the contact hole of the MOS type transistor, a nitride film is used as an etch-stop film to keep an Si substrate from being overetched. By using the contact hole as a mask, ion implantation is carried out to form the high concentration diffusion region constituting the source/drain region.

### BACKGROUND OF THE INVENTION

1. Field of the Invention

The present invention relates to a semiconductor device and a manufacturing method therefor, in particular, a MOS type transistor having a shallow high concentration junction for forming a source/drain region in a stable manner.

2. Description of the Related Art

Up to now, the following structure having a channel region 207 has been known (for example, refer to JP 2002-057326 Å (FIG. 1)). That is, a gate electrode is formed through a gate oxide film formed on a silicon semiconductor substrate, which is surrounded by a field oxide film, and low concentration diffusion layers are formed in a silicon semiconductor substrate surface on both sides of the gate electrode. In each low concentration diffusion layer, a high concentration diffusion layer called a source/drain region is formed apart from the gate electrode. Needless to say, in the silicon semiconductor substrate surface below the gate electrode, a channel region is formed.

However, along with recent miniaturization, conventional MOS type transistors of an LDD (lightly doped drain) structure are demanded to have a shallow junction. In addition, a precision prescribed is strictly imposed on depths of a contact hole and of the high concentration region forming the drain/source region, making it hard to meet the above requirement with an existing production line.

### SUMMARY OF THE INVENTION

Therefore, an object of the present invention is to provide a MOS type transistor, in which a high concentration junction can be stably formed so shallowly as to prevent a high concentration region constituting a drain/source region from extending beyond a contact hole due to a production variation, which cannot be attained by a conventional MOS type transistor of an LDD structure.

In order to attain the above-mentioned object, according to the present invention, there is employed the following means.

(1) A semiconductor device, including:

a field oxide film formed on a semiconductor substrate of one conductivity type;

a gate electrode formed through a gate oxide film on the semiconductor substrate of one conductivity type, which is surrounded by the field insulation film;

a low concentration source/drain region of a reverse conductivity type formed in a region surrounded by the field oxide film and the gate electrode;

an interlayer film for electrically isolating the gate electrode and the low concentration source/drain region of the reverse conductivity type from a wiring formed thereon;

a contact hole formed in the interlayer film for electrically connecting between the wiring, and the gate electrode and the low concentration source/drain region of the reverse conductivity type;

a nitride film formed for preventing the semiconductor substrate of one conductivity type from being overetched when forming the contact hole in the interlayer film; and

a high concentration diffusion layer of a reverse conductivity type selectively formed only in the low concentration source/drain region of the reverse conductivity type where the contact hole is formed.

(2) A semiconductor device, in which the low concentration source/drain region of the reverse conductivity type has an impurity concentration of 1×10¹⁶ to 1×10¹⁸ atoms/cm³

(3) A semiconductor device, in which the high concentration diffusion layer of the reverse conductivity type has an impurity concentration of 1×10¹⁹ to 5×10²⁰ atoms/cm³.

(4) A semiconductor device, in which the nitride film has a film thickness of 100 to 500 Å.

(5) A manufacturing method for a MOS type transistor, including:

forming a gate insulating film on a surface of a semiconductor substrate;

forming a gate electrode on the gate insulating film through patterning;

forming a low concentration diffusion region by doping an impurity into the surface of the semiconductor substrate using the gate electrode as a mask through ion implantation;

forming a nitride film over an entire surface;

forming an interlayer film containing the impurity on the entire surface of the nitride film and leveling the interlayer film through heat treatment;

selectively etching the interlayer film to form a contact hole onto the low concentration diffusion region and the gate electrode;

forming a high concentration diffusion region by doping the impurity into the surface of the semiconductor substrate using the contact hole as the mask through the ion implantation;

performing the heat treatment;

depositing a metal material into a film on the entire surface by vacuum evaporation or sputtering and patterning the metal material by photolithography or etching; and

covering the entire semiconductor substrate with a surface protective film.

(6) A manufacturing method for a semiconductor device, in which the interlayer film containing the impurity comprises a BPSG interlayer film.

(7) A manufacturing method for a semiconductor device, in which the heat treatment after the formation of the oxide film containing the impurity is carried out at 800 to 1,050° C. for 3 minutes or less for activation of the impurity.

### BRIEF DESCRIPTION OF THE DRAWINGS

In the accompanying drawings:

FIG. 1 is a schematic sectional view showing a P-channel MOS type transistor according to Embodiment 1 of the present invention;

FIG. 2 is a graph showing a relationship of a distance (S1) between one end of a gate electrode and one end of a contact hole for a source/drain region with a drain breakdown voltage;

FIG. 3 is a graph showing a relationship of a distance (S2) between one end of a channel stop below a field oxide film and one end of the contact hole for the source/drain region with the drain breakdown voltage;

FIGS. 4A to 4E are sectional views each showing, in a step order, a manufacturing method for the P-channel MOS type transistor according to Embodiment 1 of the present invention; and

FIGS. 4F to 4I are sectional views each showing, in a step order, after the step of FIG. 4E, a manufacturing method for the P-channel MOS type transistor according to Embodiment 1 of the present invention.

### DESCRIPTION OF THE PREFERRED EMBODIMENTS

With a semiconductor device according to the present invention, a MOS type transistor can be provided having a stable drain/source region, in which a high concentration region constituting the drain/source region is formed so shallowly as to prevent the region from extending beyond a contact hole due to a production variation etc.

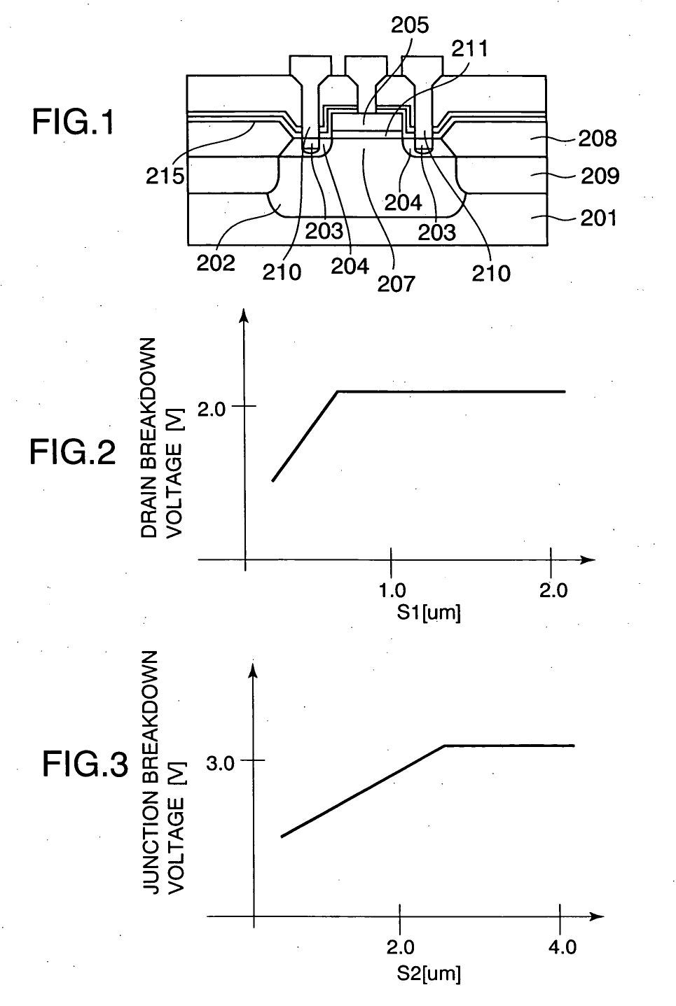

Hereinafter, referring to the accompanying drawings, a preferred embodiment of the present invention will be described. Here, a semiconductor device according to Embodiment 1 of the present invention will be described in detail. FIG. 1 is a schematic sectional view showing a P-channel MOS type transistor of the semiconductor device of the present invention.

The P-channel MOS type transistor is composed of: a gate oxide film 211 and a polycrystalline silicon gate electrode 205 formed above an N type well region 202 formed on a P type silicon semiconductor substrate 201; low concentration P− type diffusion layers 204 formed on both sides of the gate electrode on a silicon substrate surface; high concentration P+ type diffusion layers 203 formed using contact holes 210 as masks; and a channel region 207 formed therebetween. A field oxide film 208 and a channel stop region 209 are formed for isolation between elements. Note that it is not always necessary to form the N type well region using the P type silicon semiconductor substrate. A P-channel MOS type transistor may be formed on an N type silicon semiconductor substrate.

Also, in forming the N-channel MOS type transistor of a reverse conductivity type, the P type well region is formed on the N type silicon semiconductor substrate, so that the transistor is composed of the gate oxide film and the polycrystalline silicon gate electrode formed above the P type well region, low-concentration N− type diffusion layers formed on both sides of the gate electrode on the silicon substrate surface, high-concentration N+ type diffusion layers, and the channel region formed therebetween. The field oxide film and the channel stop region are formed for isolation between the elements. Note that it is not always necessary to use the N type silicon semiconductor substrate. The N-channel MOS type transistor may be formed using the P type silicon semiconductor substrate.

In general, upon forming the contact hole, dry etching is used to form the holes for minimizing a surface area therefor. With the dry etching, an Si substrate surface is also etched, causing a variation of a contact hole depth. As apparent from FIG. 1, however, in this experiment, dry etching is continuously performed to form the hole up to a nitride film and the nitride film is holed by wet etching. As a result, the contact hole can be formed without etching the Si substrate surface and causing a large damage thereon. Also, the high concentration region constituting the source/drain region is formed using the contact holes as the mask through ion implantation. As understood from this, the source/drain region is formed in a self-alignment manner. Accordingly, the stable high concentration junction substantially free of an influence of the production variation can be formed shallowly, enabling stable electric characteristics.

Also, at the same time, positions at which the contact holes are formed are changed and thus, it is possible to easily change not only a distance (S1) between one end of the gate electrode and one end of the high concentration diffusion region but also a distance (S2) between one end of the high concentration diffusion region and one end of the field oxide film. In other words, according to a required drain breakdown voltage, a junction breakdown voltage with respect to the channel stop region below the field oxide film, and an overlap capacitance of the drain/source region and the gate electrode, the widths S1, S2 of the low concentration diffusion regions and a concentration of each low concentration diffusion region are controlled. In this way, the MOS type transistor that suits high integration and high-speed operation can be obtained. Referring to FIGS. 2 and 3, an example thereof will be described.

FIG. 2 is a graph showing a relationship of the distance (S1) between one end of the gate electrode and one end of the contact hole with the drain breakdown voltage when forming the low concentration diffusion region through the ion implantation at a dosage of 2.5×10¹² atoms/cm².

As apparent from FIG. 2, the drain voltage and the distance S1 are correlatively changed. In addition, the drain breakdown voltage can be readily changed by changing the concentrations of each low concentration region and each high concentration region.

Also, FIG. 3 is a graph showing a relationship of the distance (S2) between one end of the high concentration diffusion region and one end of the field oxide film with the junction breakdown voltage with respect to the channel stop region below the oxide film. As apparent from FIG. 3, the junction breakdown voltage can be readily changed by changing the distance S2. Also, the junction breakdown voltage can be readily changed as well by changing the concentrations of the channel stop region, each low concentration diffusion region and each high concentration diffusion region.

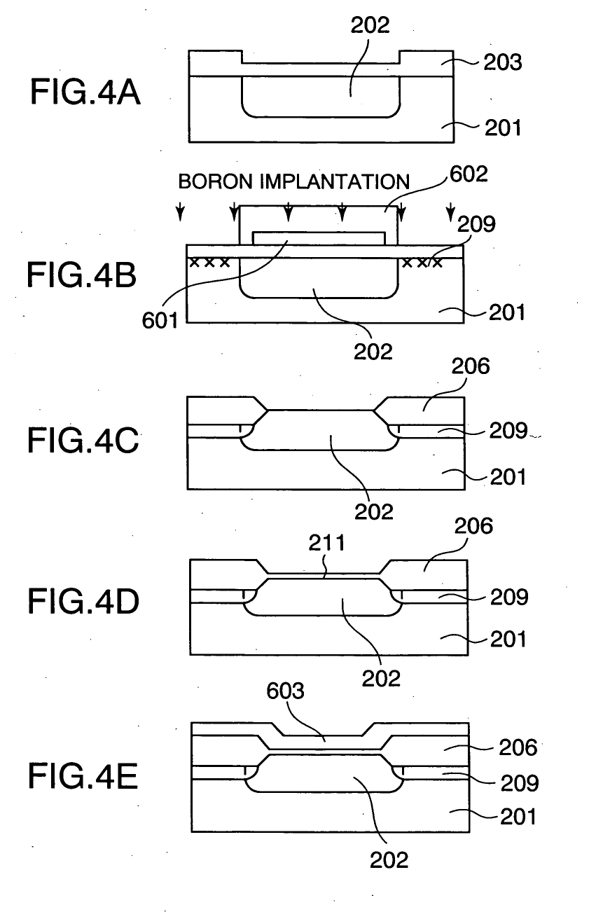

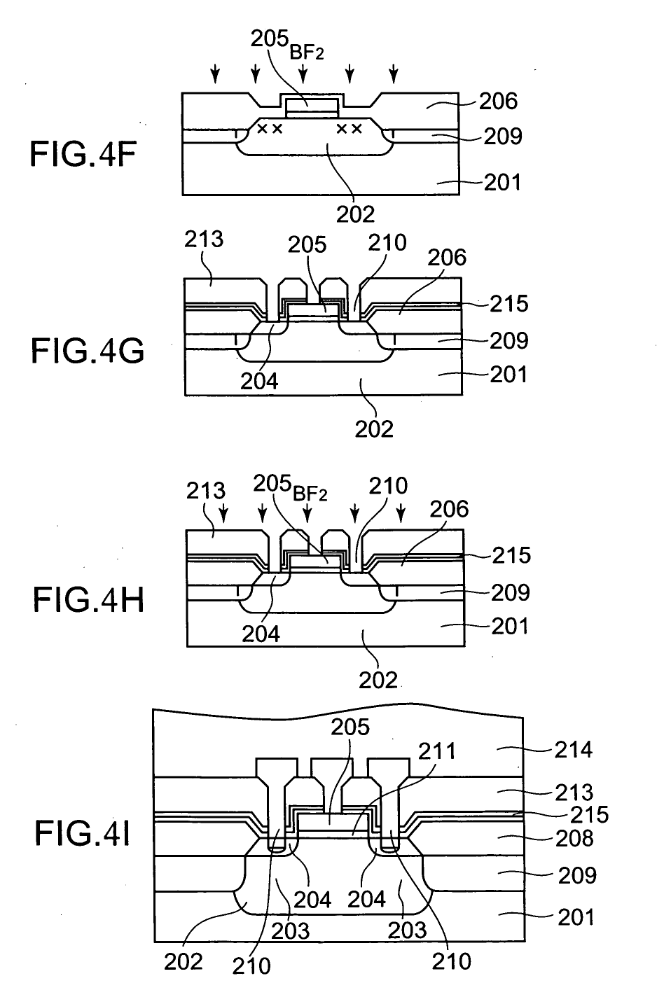

FIGS. 4A to 4I are sectional views each showing a manufacturing method for the P-channel MOS type transistor according to Embodiment 1 of the present invention in a step order.

First, in a step “A” (FIG. 4A, the same being applicable to the following description), an N well layer 202 is formed on a surface of a P type silicon semiconductor substrate 201. After forming a silicon nitride film patterned into a predetermined shape as a mask on the substrate surface, an N type impurity, for example, phosphorous is doped through the ion implantation at the dosage of 2×1012 atoms/cm². Thereafter, so-called LOCOS is performed to remove the silicon nitride film formed in the preceding step. Next, heat treatment is conducted at 1,150° C. for 6 hours, followed by diffusion and activation of the implanted impurity, i.e., phosphorous to obtain the N well layer 202 as shown in the figure. The P-channel MOS type transistor is to be formed in the N well layer 202. Note that it is not always necessary to use the P type silicon semiconductor substrate. An N type well region may be formed using the N type silicon semiconductor substrate to form the P-channel MOS type transistor in the N type well region. Alternatively, the P-channel MOS type transistor may be formed in the N type silicon semiconductor substrate.

In a step “B”, a channel stop region 209 is formed. To form this region, a silicon nitride film 601 is first formed through patterning so as to cover an active region where a transistor element is to be formed. A photoresist 602 is formed above the N well layer 202 while overlapping with the silicon nitride film 601. In this state, boron is doped as the impurity at an acceleration energy of 30 KeV and a dosage of 2×10¹³ atoms/cm² through the ion implantation to thereby complete the channel stop region 209. As shown in the figure, the channel stop region 209 is formed in a portion including an element region.

Subsequently, in a step “C”, a field oxide film 206 is formed to surround the element region by the so-called LOCOS. After that, sacrificial oxidation and removal treatment therefor are performed to remove a foreign matter remaining on the substrate surface and clean the same.

In a step “D”, thermal oxidation treatment is performed on the substrate surface in an H₂O atmosphere to form a gate oxide film 211. In the present invention, the thermal oxidation treatment is performed in the H₂O atmosphere at 860° C. to form the oxide film with a thickness of about 300 Å. In general, a gate insulating film formed from the thermally oxidized film should have a thickness of about 3 MV/cm for securing a reliability of the semiconductor device. For example, the MOS type transistor of 30 V in power source voltage requires the oxide film thickness of 1,000 Å or more.

Next, in a step “E”, a polysilicon 603 is deposited on the gate oxide film 211 by CVD. In the present invention, the polysilicon is deposited into a film with a thickness of 4,000 Å. In order to form a gate electrode 205 for the MOS transistor, the polysilicon 603 is changed into an N type conductivity. For that purpose, phosphorous as an impurity element is doped into the polysilicon 603 at a high concentration through the ion implantation or in an impurity diffusion furnace. An implantation concentration is set as follows: ion implantation amount/polysilicon film thickness=2×10¹⁹ atoms/cm³ or more. Note that it is not always necessary for the gate electrode for the MOS transistor to have the N type conductivity; boron as the impurity element may be doped at the high concentration instead through the ion implantation or in the impurity diffusion furnace to impart a P type conductivity.

Next, in a step “F” (FIG. 4F, the same being applicable to the following description), the photoresist formed in the preceding step is removed, after which the low concentration diffusion layers 204 of the P type MOS transistor are formed. In this state, BF₂ or boron as the P type impurity is doped in a self-alignment manner using the gate electrode 205 as a mask at the dosage of 1×10¹² to 1×10¹³ atoms/cm² through the ion implantation, that is, about 1×10¹⁶ to 1×10¹⁸ atoms/cm³ in terms of concentration.

Subsequently, in a step “G”, the low concentration diffusion layers 204 of the P-channel MOS type transistor are formed, followed by removing the photoresist. A nitride film is formed on the entire surface, which is etched above the P type silicon semiconductor substrate 201 at the time of forming the contact holes. The nitride film is formed by, for example, CVD. Following this, a BPSG interlayer film 213 is formed on the entire surface, for example. The interlayer film is formed by, for example, CVD and is successively subjected to the heat treatment at 900 to 950° C. for about 30 minutes to 2 hours to be leveled. Subsequently, the interlayer film 213 is selectively etched to form a contact hole 210 onto each high concentration diffusion region 203 and the gate electrode 205. In the present invention, upon forming the contact holes, the dry etching is first conducted, followed by wet etching to remove the interlayer film, e.g., the BPSG interlayer film. Then, the etching is selectively performed up to the nitride film, followed by removing the nitride film by wet etching. In the present invention, the nitride film having a thickness of 100 to 500 Å is formed.

Subsequently, in a step “H”, BF₂ as a P type impurity is doped in a self-alignment manner using the contact hole 210 as a mask at the dosage of 3×10¹⁵ to 5×10¹⁶ atoms/cm² through the ion implantation, that is, about 1×10¹⁹ to 5×10²⁰ atoms/cm³ in terms of concentration. Thereafter, the heat treatment is carried out for the activation of the ion-implanted impurity and an adjustment of a contact condition. In the present invention, the heat treatment is carried out at 800 to 1,050° C. for 3 minutes or less.

Subsequently, in a step “I”, a metal material is deposited into a film over the entire surface through vacuum evaporation or sputtering, followed by patterning the film into a metal wiring 212 by photolithography or etching. The entire substrate is covered with a surface protective film 214.

Given above is the description of the embodiment of the P-channel MOS type transistor; however, the same effects can be obtained by using the impurity of the reverse conductivity type to form the N-channel MOS type transistor.

As set forth, according to the present invention, ion implantation is carried out by using the contact hole as a mask for forming the high concentration diffusion region constituting the source/drain region of the MOS type transistor. This makes it possible to provide the MOS type transistor with a simple process, in which a high concentration region constituting a drain/source region is prevented from extending beyond a contact hole due to a production variation, which cannot be attained by a conventional MOS type transistor of an LDD structure.

What is claimed is:

1. A semiconductor device comprising:
a field oxide film formed on a semiconductor substrate of one conductivity type;
a gate electrode formed through a gate oxide film on the semiconductor substrate of one conductivity type, which is surrounded by the field insulation film;
a low concentration source/drain region of a reverse conductivity type formed in a region surrounded by the field oxide film and the gate electrode;
an interlayer film for electrically isolating the gate electrode and the low concentration source/drain region of the reverse conductivity type from a wiring formed thereon;
a contact hole formed in the interlayer film for electrically connecting between the wiring, and the gate electrode and the low concentration source/drain region of the reverse conductivity type;
a nitride film formed for preventing the semiconductor substrate of one conductivity type from being overetched when forming the contact hole in the interlayer film; and
a high concentration diffusion layer of a reverse conductivity type selectively formed only in the low concentration source/drain region of the reverse conductivity type where the contact hole is formed.

2. A semiconductor device according to claim 1, wherein the low concentration source/drain region of the reverse conductivity type has an impurity concentration of 1×10¹⁶ to 1×10¹⁸ atoms/cm³.

3. A semiconductor device according to claim 1, wherein the high concentration diffusion layer of the reverse conductivity type has an impurity concentration of 1×10¹⁹ to 5×10²⁰ atoms/cm³.

4. A semiconductor device according to claim 1, wherein the nitride film has a film thickness of 100 to 500 Å.

5. A manufacturing method for a MOS type transistor comprising:
forming a gate insulating film on a surface of a semiconductor substrate;
forming a gate electrode on the gate insulating film through patterning;
forming a low concentration diffusion region by doping an impurity into the surface of the semiconductor substrate using the gate electrode as a mask through ion implantation;
forming a nitride film over an entire surface;
forming an interlayer film containing the impurity on the entire surface of the nitride film and leveling the interlayer film through heat treatment;
selectively etching the interlayer film to form a contact hole onto the low concentration diffusion region and the gate electrode;
forming a high concentration diffusion region by doping the impurity into the surface of the semiconductor substrate using the contact hole as the mask through the ion implantation;
performing the heat treatment;
depositing a metal material into a film on the entire surface by vacuum evaporation or sputtering and patterning the metal material by photolithography or etching; and
covering the entire semiconductor substrate with a surface protective film.

6. A manufacturing method for a semiconductor device according to claim 5, wherein the interlayer film containing the impurity comprises a BPSG interlayer film.

7. A manufacturing method for a semiconductor device according to claim 5, wherein the heat treatment after the formation of the oxide film containing the impurity is carried out at 800 to 1,050° C. for 3 minutes or less for activation of the impurity.
